(19) United States
(12) Patent Application Publication
(10) Pub. No.: US 2002/0032892 A1
(43) Pub. Date: Mar. 14, 2002

(54) Method and system for recording and transmitting digital data and improved error correcting code table

(75) Inventor: Satoshi Itoi, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/942,730

(22) Filed: Aug. 31, 2001

(30) Foreign Application Priority Data
Aug. 31, 2000 (JP) 2000-264546

(51) Int. Cl. H03M 13/00

(52) U.S. Cl. 714/784

(57) ABSTRACT

The present invention provides a method of implementing at least one of recording and transmitting digital data, under conditions that a total code length including data and error correcting codes corresponds to not less than 256 symbols, and each of the symbols comprises n-bits, where n is larger than 8.

### BACKGROUND OF THE INVENTION

1. Field of the Invention

The present invention relates to a method and an apparatus for recording and transmitting digital data, and more particularly to a method of preparing an error correcting code table and an improved error correcting code table for recording and transmitting digital data.

2. Description of the Related Art

A digital versatile disc (hereinafter referred to as DVD) has been known as a digital data storage medium. FIG. 1 is a diagram illustrative of a structure of a block table of an error correcting code (hereinafter referred to as ECC) in DVD. DVD has 192×172 symbol matrix arrays. 192 is the row number, and 172 column number. One symbol comprises eight bits. The error correcting code is a Reed-Solomon Code. An external code error correcting code has a code length of 208, a data length of 192, a minimum distance “dmin” of 17. An internal code error correcting code has a code length of 182, a data length of 172, a minimum distance “dmin” of 11. 131 represents one symbol of eight bits. 132 represents a data table. 133 represents the external code error correcting code. 134 represents the internal code error correcting code. 135 represents a sector comprising twelve rows of data. The data table 132 has 33024 symbols of data, which are classified into sixteen sectors 135. One sector 135 comprises 2064 bytes. After calculating the error correcting code, the external error correcting code 133 is divided into sixteen rows and then each row is inserted after the end of each sector 135. The each sector 135 comprises twelve rows of data and a single row of the external code error correcting code. Namely, the each sector 135 has thirteen rows. The each sector 135 is further added with a sector header. The each sector 135 is a minimum undividable unit for recording the each sector 135 as the unit into the optical disk. The internal code error correcting code 134 is accompanied to the data of the sector 135 and the external code error correcting code 133. Data transmission to a host system controlling an optical disk drive are made for each sector as the minimum undividable unit.

A high density recording for the optical disk is desirable. It is, therefore, desirable to reduce a bit wavelength and a track pitch. A burst error due to a wound and a dust provides a large influence to a large number of data bits, for which reason it is desirable to counter-measure the burst error or emphasize the error correction performance. The Reed-Solomon codes are used as the error correcting codes, for which reason the code length is limited within 256 bytes. An upper limit of a total of the data and the error correcting codes is 255 bytes in each of the row and column directions over the error correcting code block table. If the redundancy occupied by the error correcting code is just the upper limit, the burst error can be corrected at only a few thousands bytes.

In the above circumstances, the development of novel method and apparatus for recording and transmitting digital data free from the above problems is desirable.

### SUMMARY OF THE INVENTION

Accordingly, it is an object of the present invention to provide a novel method of recording and transmitting digital data free from the above problems.

It is a further object of the present invention to provide a novel method of recording and transmitting digital data for allowing a large size table including more than 256×256 symbols and for correcting burst errors of a large symbol number.

It is a still further object of the present invention to provide a novel method of recording and transmitting digital data improved in correcting performance to random errors in a unit of a single symbol.

It is yet a further object of the present invention to provide a novel apparatus of recording and transmitting digital data free from the above problems.

It is a further object of the present invention to provide a novel apparatus of recording and transmitting digital data for allowing a large size table including more than 256×256 symbols and for correcting burst errors of a large symbol number.

It is a still further object of the present invention to provide a novel apparatus of recording and transmitting digital data improved in correcting performance to random errors in a unit of a single symbol.

It is another object of the present invention to provide a novel method of preparing an improved error correcting code table free from the above problems.

It is a further object of the present invention to provide a novel method of preparing an improved error correcting code table for allowing a large size table including more than 256×256 symbols and for correcting burst errors of a large symbol number.

It is a still further object of the present invention to provide a novel method of preparing an improved error correcting code table improved in correcting performance to random errors in a unit of a single symbol.

It is still another object of the present invention to provide a novel error correcting code table free from the above problems.

It is a further object of the present invention to provide a novel error correcting code table for allowing a large size table including more than 256×256 symbols and for correcting burst errors of a large symbol number.

It is a still further object of the present invention to provide a novel error correcting code table improved in correcting performance to random errors in a unit of a single symbol.

It is yet another object of the present invention to provide a novel method of using an improved error correcting code table free from the above problems.

It is a further object of the present invention to provide a novel method of using an improved error correcting code table for allowing a large size table including more than 256×256 symbols and for correcting burst errors of a large symbol number.

It is a still further object of the present invention to provide a novel method of using an improved error correcting code table improved in correcting performance to random errors in a unit of a single symbol.

The present invention provides a method of implementing at least one of recording and transmitting digital data, under conditions that a total code length including data and error correcting codes corresponds to not less than 256 symbols, and each of the symbols comprises n-bits, where n is larger than 8.

The present invention also provides a method of preparing a table including at least data and error correcting codes, wherein a total code length including the data and the error correcting codes corresponds to not less than 256 symbols, and each of the symbols comprises n-bits, where n is larger than 8.

The present invention also provides a table including at least data and error correcting codes, wherein a total code length including the data and the error correcting codes corresponds to not less than 256 symbols, and each of the symbols comprises n-bits, where n is larger than 8.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIG. 1 is a diagram illustrative of a structure of a block table of ECC for DVD.

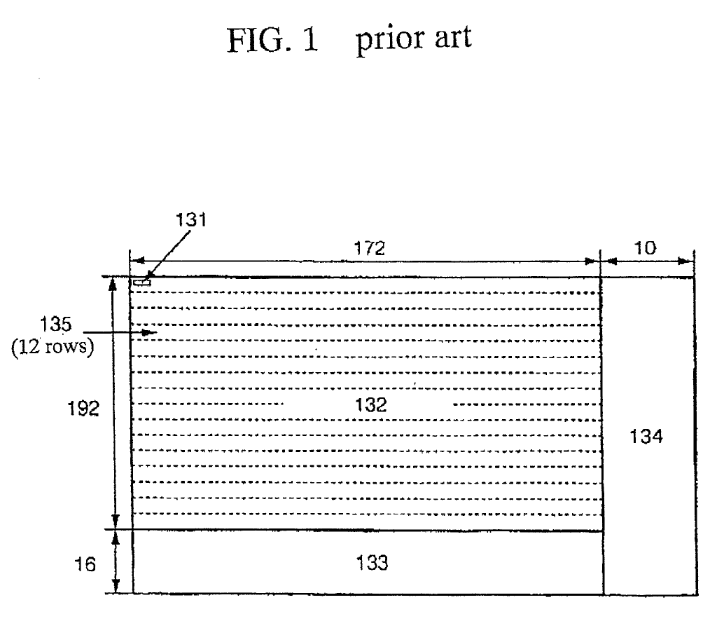

FIG. 2 is a diagram illustrative of a novel structure of a block table of ECC for DVD in a first embodiment in accordance with the present invention.

FIG. 3 is a diagram illustrative of a novel structure of a block table of ECC for DVD in a second embodiment in accordance with the present invention.

FIG. 4 is a diagram of a symbol structure on a top row of the internal code error correcting code of FIG. 3 in a second embodiment in accordance with the present invention.

FIG. 5 is a diagram of a symbol structure on columns “0” and “1” of the external code error correcting code of FIG. 3 in a second embodiment in accordance with the present invention.

FIG. 6 is a diagram of a symbol structure on columns “0” and “1” of the external code error correcting code of FIG. 3 in a third embodiment in accordance with the present invention.

FIG. 7 is a diagram illustrative of a novel structure of a block table of ECC for DVD in a fourth embodiment in accordance with the present invention.

FIG. 8 is a diagram of a symbol structure on a top row of the internal code error correcting code of FIG. 7 in a fourth embodiment in accordance with the present invention.

FIG. 9 is a diagram of a symbol structure on columns “0” and “1” of the external code error correcting code of FIG. 7 in a fourth embodiment in accordance with the present invention.

FIG. 10 is a diagram of a symbol structure on columns “0” and “1” of the external code error correcting code in a fifth embodiment in accordance with the present invention.

FIG. 11 is a diagram illustrative of a novel structure of a block table of ECC for DVD in a sixth embodiment in accordance with the present invention.

FIG. 12 is a diagram illustrative of a novel structure of a block table of ECC for DVD in a seventh embodiment in accordance with the present invention.

FIG. 13 is a block diagram illustrative of a digital data recording and transmitting system to be used for realizing the present invention.

### DETAILED DESCRIPTION OF THE PREFERRED EMBODIMENTS

A first aspect of the present invention is a method of implementing at least one of recording and transmitting digital data, under conditions that a total code length including data and error correcting codes corresponds to not less than 256 symbols, and each of the symbols comprises n-bits, where n is larger than 8.

It is possible to further comprise the steps of arraying the data and the error correcting codes in a matrix of plural rows and plural columns; calculating external code error correcting codes for all column-directional alignments of data in a column direction, and further internal code error correcting codes for all row-directional alignments of data in a column direction or the external code error correcting codes; and recording the data and the calculated external and internal code error correcting codes.

It is also possible that the error correcting codes are Reed-Solomon codes over GF (2ⁿ).

It is also possible that the data are arrayed in a matrix of plural rows and plural columns, and a total data length corresponds to a number of symbols, which is equal to or multiply of 2064.

It is also possible that the data are arrayed in a matrix of plural rows and plural columns, and a total data length corresponds to a number of symbols which is equal to or multiply of 33024.

It is also possible that the data are arrayed in a matrix of plural rows and plural columns, and a total data length of the rows corresponds to a number of symbols which is equal to or multiply of 192.

It is also possible that the data are arrayed in a matrix of plural rows and plural columns, and a total data length of the columns corresponds to a number of symbols which is equal to or multiply of 172.

It is also possible that external code error correcting codes are isolated into a first block comprising even number rows and a second block comprising odd number rows. It is further possible that calculations of the external code error correcting codes are made with a row-directional increment of 2 or more integer.

It is also possible that calculations of the error correcting codes are made with a second column-directional increment of 2 or more integer.

It is also possible to further comprise the steps of arraying the data and the error correcting codes in a matrix array of plural rows and plural columns; dividing the data and the error correcting codes into a plurality of sectors; and adding at least an additional information to each of the sectors to form each logic segment. It is further possible that the each segment has a segment size of 2048 bytes. It is also possible that the each segment has a segment size of 2064 bytes, which comprises 2048 bytes for data and 16 bytes for segment header. It is also possible that each external code error correcting code is placed following to an end of the each sector. It is also possible that each external code error correcting code is placed on a center region of the matrix array. It is also possible that a length of the each symbol is equal to a bit length of coded data.

A second aspect of the present invention is a method of preparing a table including at least data and error correcting codes, wherein a total code length including the data and the error correcting codes corresponds to not less than 256 symbols, and each of the symbols comprises n-bits where n is larger than 8.

It is also possible to further comprise the steps of: arraying the data and the error correcting codes in a matrix of plural rows and plural columns; and calculating external code error correcting codes for all column-directional alignments of data in a column direction, and further internal code error correcting codes for all row-directional alignments of data in a column direction or the external code error correcting codes.

It is also possible that the error correcting codes are Reed-Solomon codes over GF (2ⁿ).

It is also possible that the data are arrayed in a matrix of plural rows and plural columns, and a total data length corresponds to a number of symbols, which is equal to or multiply of 2064.

It is also possible that the data are arrayed in a matrix of plural rows and plural columns, and a total data length corresponds to a number of symbols which is equal to or multiply of 33024.

It is also possible that the data are arrayed in a matrix of plural rows and plural columns, and a total data length of the rows corresponds to a number of symbols which is equal to or multiply of 192.

It is also possible that the data are arrayed in a matrix of plural rows and plural columns, and a total data length of the columns corresponds to a number of symbols which is equal to or multiply of 172.

It is also possible that external code error correcting codes are isolated into a first block comprising even number rows and a second block comprising odd number rows. It is also possible that calculations of the external code error correcting codes are made with a row-directional increment of 2 or more integer

It is also possible that calculations of the error correcting codes are made with a second column-directional increment of 2 or more integer.

It is also possible to further comprise the steps of arraying the data and the error correcting codes in a matrix array of plural rows and plural columns; dividing the data and the error correcting codes into a plurality of sectors and adding at least an additional information to each of the sectors to form each logic segment.

It is also possible that the each segment has a segment size of 2048 bytes.

It is also possible that the each segment has a segment size of 2064 bytes, which comprises 2048 bytes for data and 16 bytes for segment header.

It is also possible that each external code error correcting code is placed following to an end of the each sector.

It is also possible that each external code error correcting code is placed on a center region of the matrix array.

It is also possible that a length of the each symbol is equal to a bit length of coded data.

A third aspect of the present invention is a table including at least data and error correcting codes, wherein a total code length including the data and the error correcting codes corresponds to not less than 256 symbols, and each of the symbols comprises n-bits, where n is larger than 8.

It is also possible that the table comprises a matrix array of the data and the error correcting codes over plural rows and plural columns; and the error correcting codes includes external code error correcting codes for all column-directional alignments of data in a column direction, and internal code error correcting codes for either one of all row-directional alignments of data in a column direction or the external code error correcting codes.

It is also possible that the error correcting codes are Reed-Solomon codes over GF (2ⁿ).

It is also possible that the table has a data array of plural rows and plural columns, and a total data length corresponds to a number of symbols, which is equal to or multiply of 2064.

It is also possible that the table has a data array of plural rows and plural columns, and a total data length corresponds to a number of symbols which is equal to or multiply of 33024.

It is also possible that the table has a data array of plural rows and plural columns, and a total data length of the rows corresponds to a number of symbols which is equal to or multiply of 192.

It is also possible that the table has a data array of plural rows and plural columns, and a total data length of the columns corresponds to a number of symbols which is equal to or multiply of 172.

It is also possible that external code error correcting codes are isolated into a first block comprising even number rows and a second block comprising odd number rows.

It is also possible that the table has a matrix array comprising the data and the error correcting codes over plural rows and plural columns, and the matrix array has a plurality of logic segments, and each of the logic segments includes each sector and an additional information, and the each sector including at least one of the data and the error correcting codes. It is also possible that the each segment has a segment size of 2048 bytes. It is also possible that the each segment has a segment size of 2064 bytes, which comprises 2048 bytes for data and 16 bytes for segment header.

It is also possible that each external code error correcting code is positioned following to an end of the each sector. It is also possible that each external code error correcting code is positioned on a center region of the matrix array. It is also possible that a length of the each symbol is equal to a bit length of coded data.

First Embodiment:

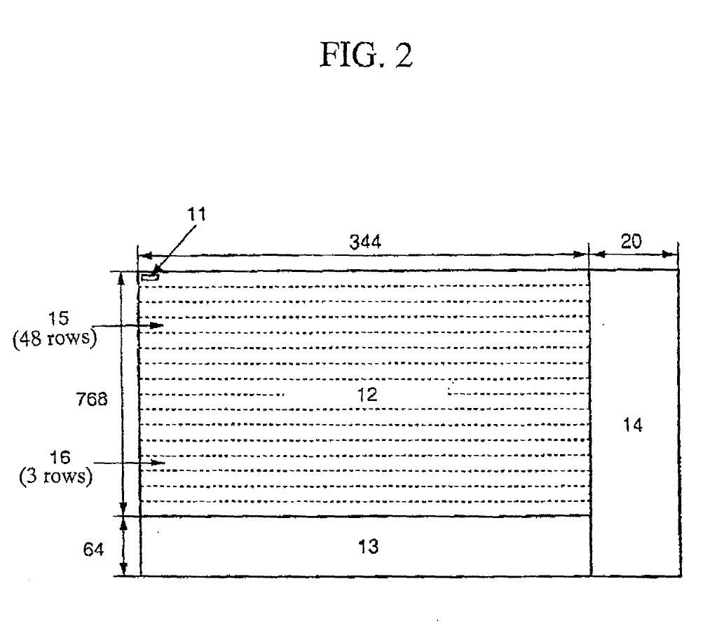

A first embodiment according to the present invention will be described in detail with reference to the drawings. FIG. 2 is a diagram illustrative of a novel structure of a block table of ECC for DVD in a first embodiment in accordance with the present invention.

The block table comprises 16-bits units. One symbol comprises 16 bits. The row number is 768. Each row includes 344 data symbols. The error correcting code is the Reed-Solomon Code over GF (2¹⁶). An external code error correcting code has a code length of 832, a data length of 768, a minimum distance “dmin” of 65. An internal code error correcting code has a code length of 364, a data length of 344, a minimum distance “dmin” of 21. 11 represents a single symbol. 12 represents a data table. 13 represents an external code error correcting code. 14 represents an internal code error correcting code, 15 represents a single sector which comprises 48 rows. 16 represents a single logic segment comprising 3 rows. The single symbol comprises 16 bits and the error correcting code is the Reed-Solomon Code over GF (2¹⁶), for which reason a maximum code length corresponds to 65535 symbols. The data table 12 allows 768×344 arrays of symbols.

Operations of recording digital data onto the block table will be described with reference to FIG. 2. As an external code error correcting code on a first column of the data table 12, Reed-Solomon codes of 64 symbols are generated to the data of 768 symbols on the first column. The generated codes are aligned on the first column of the external code error correcting code. This calculation process will be repeated for all columns, for examples second to 344^{th} columns, so that the external code error correcting codes 13 for the 344 columns are thus generated and aligned. As an internal code error correcting code on the first row of the data table 12, Reed-Solomon codes of 20 symbols are generated to the data of 344 symbols on the first column. The generated codes are aligned on the first row of the internal code error correcting code. This calculation process will be repeated for all rows, for examples second to 832^{th} rows including 64 rows of the above external code error correcting codes, so that the internal code error correcting codes 14 for the 832 rows are thus generated and aligned.

The data table 12 is free of the external and internal code error correcting codes 13 and 14. The data table 12 is divided into sixteen sectors 15, each of which comprises 48 rows and 344 columns. The external and internal code error correcting codes are distributed into data of the sector 15. A data size of the single sector 15 is larger than 48×344=16512 symbols=33024 bytes. The data in the each sector 15, and the external and internal code error correcting codes distributed therein are further added with sector headers, addresses, clock data for PLL-lock thereby to form a sector data sequence for subsequent recording the same onto the disk.

Table data of one sector 15 free of the error correcting code is divided into sixteen logic segments, each of which comprises 3 rows and 344 columns. The single logic segment 16 has a size 3×344=1032 symbols=2064 bytes. The real data occupy 2048 bytes. Informations such as the error correcting codes occupy 16 bytes. Communications to and from the host system may be made by the real data only in a unit of the 2048 bytes or by both the real data and the informations such as the error detecting codes in another unit of the 2064 bytes. The host system corresponds to any functional block. If the optical disk drive is used as a video disk recorder, then an image compression extension block, a voice compression extension block, a file system, a user interface, and a system controller are examples of the host system.

Data compatibility between the error correcting code block table and the DVD will be described. In DVD, the single error correcting code block comprises sixteen sectors or 33024 bytes, wherein the single sector comprises 2064 bytes. The 2064 bytes of the single sector comprises 2048 bytes of the read data and 16 bytes of informations such as error detecting codes. The error correcting code block is a data unit for correcting errors. The each sector is added with a sector header, an address, and clock data for PLL-lock. The error correcting code block is the minimum undividable unit for reducing the data onto the disk or for data transmissions to and from the host system.

The data table 12 of the error correcting code block table has a total data byte number which is a multiple of 2064 which corresponds to the single sector of DVD. The symbols are aligned in matrix of 768 rows by 344 columns. The single symbol comprises two bytes. The one row includes 688 bytes. The three rows include 2064 bytes. Namely, the single sector is placed over the three rows. The single sector of DVD is allocated to the single logic segment 16 of the data table 12. Sixteen sectors of DVD are allocated to the single sector 15 of the data table 12. 256 sectors of DVD are allocated to the 768 rows of the data table 12. Data corresponding to the integer number of the sectors are allocated to the error correcting code block table, for which reason an efficient data recording operation of DVD can be realized.

The total data byte number of the data table 12 of the error correcting code block table is a multiple of 33024 corresponding to the single error correcting code block of DVD. Symbols are aligned in a matrix of 768 rows by 344 columns. The single symbol comprises two bytes. The one row includes 688 bytes. The single sector 15 comprises 33024 bytes The single error correcting code block of DVD is placed on the single sector 15. Namely, sixteen error correcting code blocks of DVD are placed on the 768 rows of the data table 12. Data of an integer number time of the error correcting code blocks of DVD are placed on the error correcting code block table, for which reason an efficient data recording operation of DVD can be realized.

The data byte number of the data table 12 of the error correcting code block table is an integer number time of a data byte number of the single sector or the single error correcting code block of DVD, for which purpose, it is convenient and effective measure that the row number of the data table 12 is an integer number time of 192 which is the row number of DVD and/or the column number of the data table 12 is an integer number time of 172 which is the column number of DVD.

Second Embodiment:

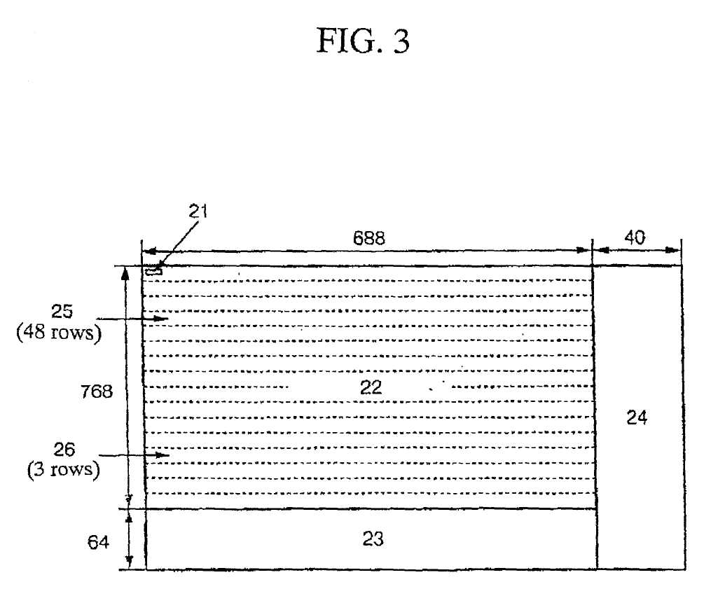

A second embodiment according to the present invention will be described in detail with reference to the drawings. FIG. 3 is a diagram illustrative of a novel structure of a block table of ECC for DVD in a second embodiment in accordance with the present invention.

The block table comprises 8-bits units. One symbol comprises 16 bits. The row number is 768. Each row includes 688 data bytes. The error correcting code is the Reed-Solomon Code over GF (2¹⁶). An external code error correcting code has a code length of 832, a data length of 768, a minimum distance “dmin” of 65. An internal code error correcting code has a code length of 364, a data length of 344, a minimum distance “dmin” of 21. 21 represents a single byte. 22 represents a data table. 23 represents an external code error correcting code 24 represents an internal code error correcting code. 25 represents a single sector which comprises 48 rows. 26 represents a single logic segment comprising 3 rows.

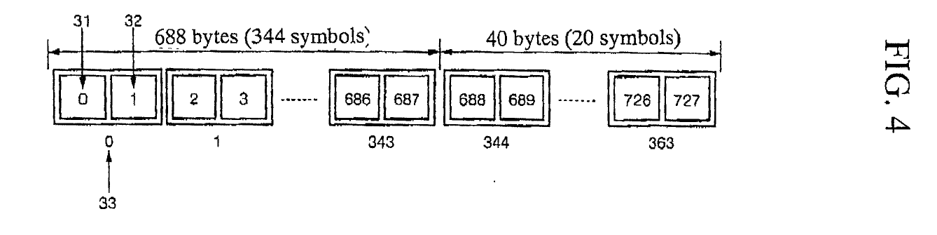

FIG. 4 is a diagram of a symbol structure on a top row of the internal code error correcting code of FIG. 3 in a second embodiment in accordance with the present invention. In a recording side, the external code error correcting code is added before the internal code error correcting code is then added. In a reproducing side, the internal code error correcting code is decoded before the external code error correcting code is then decoded.

31 represents a data byte number 0 on a column number “0”. 32 represents a data byte number 1 on a column number “1”. A largest data byte number is 687. The data on the single low comprise 688 bytes or 344 symbols. The internal code error correcting code comprises data byte numbers 688 to 727 of 40 bytes or 20 symbols. 33 represents a symbol of the symbol number “0”, wherein this single symbol comprises 2 bytes or 16 bits which comprise two data bytes of the data byte numbers “0” and “1”. In case that the single symbol comprises the data byte numbers “0” and “1”, it is general that the production method of the internal code error correcting code is the same as that of the external code error correcting code. It is, however, possible that the production method of the internal code error correcting code is different from that of the external code error correcting code. The data symbol comprises the symbol numbers “0” to “343”, or 344 symbols. The internal code error correcting code comprises 20 symbols, for example, symbol numbers “344” to “363”. The internal code error correcting code is the Reed-Solomon code over GF (2¹⁶). The Reed-Solomon code of 20 symbols is produced for the data of 344 symbols. The internal code error correcting code 24 is set on the row number “1”. This calculation will be repeated for 768 rows of the data table 12 and 64 rows of the external code error correcting code 23, so that the Reed-Solomon codes are produced and set as the internal code error correcting codes 24 for 832 rows in total.

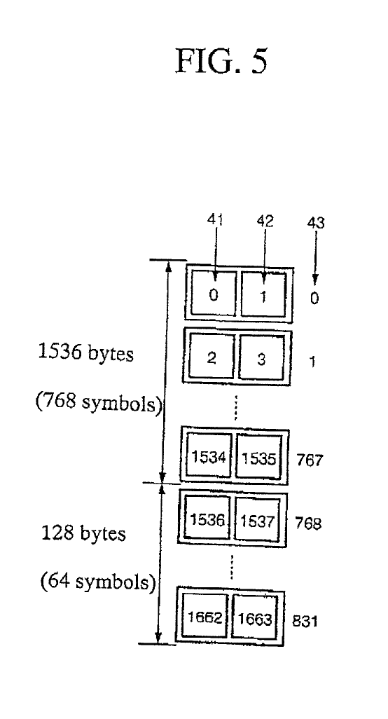

FIG. 5 is a diagram of a symbol structure on columns “0” and “1” of the external code error correcting code of FIG. 3 in a second embodiment in accordance with the present invention. 41 represents a data byte number 0 on a row number “0” and a column number “0”. 42 represents a data byte number 1 on a row number “0” and a column number “1”. A largest data byte number is 1535. The data on the single row comprise 1536 bytes. Thc external code error correcting code comprises data byte numbers 1536 to 1663 of 128 bytes.

43 represents a symbol of the symbol number “0”, wherein this single symbol comprises 2 bytes or 16 bits which comprise two data bytes of the data byte numbers “0” and “1”. In case that the single symbol comprises the data byte numbers “0” and “1”, either one of the data byte numbers “0” and “1” may be placed in MSB-side. The data symbol comprises the symbol numbers “0” to “767”, or 768 symbols. The external code error correcting code comprises 64 symbols, for example, symbol numbers “768” to “831”. The external code error correcting code is the Reed-Solomon code over GF (2¹⁶). The Reed-Solomon code of 20 symbols is produced for the data of 344 symbols. The Reed-Solomon codes of 64 symbols are produced to the data of 768 symbols for each column. This calculation will be repeated for 688 columns including the data table 22 and the external code error correcting code 23, so that the Reed-Solomon codes are produced and set as the external code error correcting codes 23.

Third Embodiment:

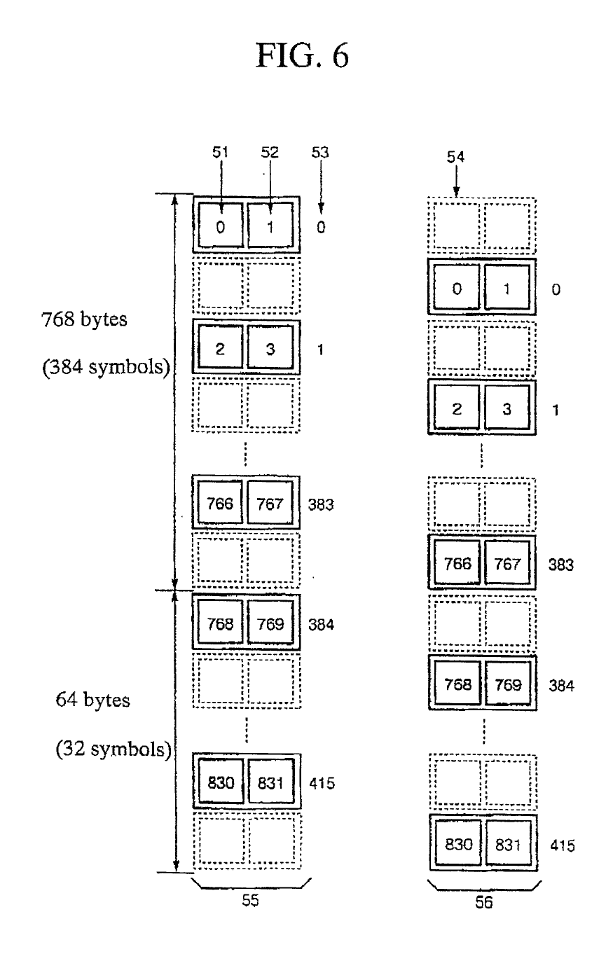

A third embodiment according to the present invention will be described in detail with reference to the drawings. The third embodiment is different from the second embodiment in the method of producing the external code error correcting codes. FIG. 6 is a diagram of a symbol structure on columns “0” and “1” of the external code error correcting code of FIG. 3 in a third embodiment in accordance with the present invention. In a recording side, the external code error correcting code is added before the internal code error correcting code is then added. In a reproducing side, the internal code error correcting code is decoded before the external code error correcting code is then decoded. 55 represents a block of even number rows and column numbers “0” and “1” 56 represents an adjacent block of odd number rows and column numbers “0” and “1”.

In the block 55, 51 represents a data byte number 0 on a row number “0” and a column number “0”. 52 represents a data byte number 1 on a row number “0” and a column number “1”. A largest data byte number is 767 on the row number “766” and the column number “1”. The data on the block 55 comprise 768 bytes. The external code error correcting code comprises a data byte number 768 on the row number “768” and the column number “0” to a data byte number 831 on the row number “830” and the column number “1”. The external code error correcting code comprises 64 bytes.

In the block 56, a data byte number 0 is on a row number “1” and a column number “0”. A data byte number 1 on a row number “1” and a column number “1”. A largest data byte number is 767 on the row number “767” and the column number “1”. The data on the block 56 comprise 768 bytes. The external code error correcting code comprises a data byte number 768 on the row number “769” and the column number “0” to a data byte number 831 on the row number “831” and the column number “1”. The external code error correcting code comprises 64 bytes. 54 with a broken line represents a data belonging to other block. In the block 55, 53 represents a symbol of the symbol number “0”, wherein this single symbol comprises 2 bytes or 16 bits which comprise two data bytes of the data byte numbers “0” and “1”. In case that the single symbol comprises the data byte numbers “0” and “1”, either one of the data byte numbers “0” and “1” may be placed in MSB-side. The data symbol comprises the symbol numbers “0” to “383”, or 384 symbols. The external code error correcting code comprises 32 symbols, for example, symbol numbers “384” to “415”.

In the block 56, the symbol number “0” comprises 2 bytes or 16 bits which comprise two data bytes of the data byte numbers “0” and “1”. In case that the single symbol comprises the data byte numbers “0” and “1”, either one of the data byte numbers “0” and “1” may be placed in MSB-side. The data symbol comprises the symbol numbers “0” to “383”, or 384 symbols. The external code error correcting code comprises 32 symbols, for example, symbol numbers “384” to “415”.

In each of the blocks 55 and 56, the external code error correcting code is the Reed-Solomon code over GF (2¹⁶). The Reed-Solomon code of 32 symbols is produced for the data of 348 symbols. In total of the blocks 55, and 56, the Reed-Solomon codes of 64 symbols are produced to the data of 768 symbols for each column. In each of the blocks 55 and 56, this calculation will be repeated for 688 columns including the data table 22 and the external code error correcting code 23, so that the Reed-Solomon codes are produced and set as the external code error correcting codes 23.

Fourth Embodiment:

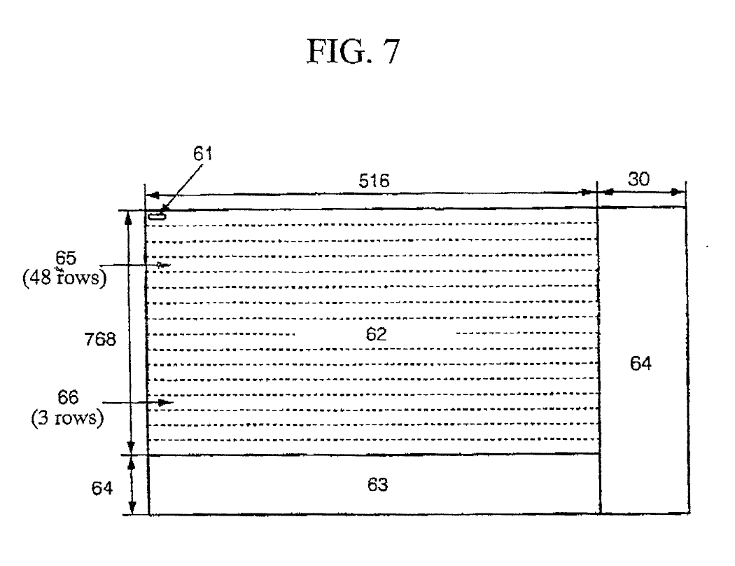

A fourth embodiment according to the present invention will be described in detail with reference to the drawings. FIG. 7 is a diagram illustrative of a novel structure of a block table of ECC for DVD in a fourth embodiment in accordance with the present invention.

The block table comprises 8-bits units. One symbol comprises 12 bits. The row number is 768. Each row includes 516 data bytes. The error correcting code is the Reed-Solomon Code over GF (2¹²). An external code error correcting code has a code length of 1664, a data length of 1536, a minimum distance “dmin” of 129. Alternatively, the external code error correcting code has a code length of 832, a data length of 768, a minimum distance “dmin” of 65. An internal code error correcting code has a code length of 364, a data length of 344, a minimum distance “dmin” of 21. 61 represents a single byte. 62 represents a data table. 63 represents an external code error correcting code. 64 represents an internal code error correcting code. 65 represents a single sector which comprises 48 rows. 66 represents a single logic segment comprising 3 rows. In a recording side, the external code error correcting code is added before the internal code error correcting code is then added. In a reproducing side, the internal code error correcting code is decoded before the external code error correcting code is then decoded.

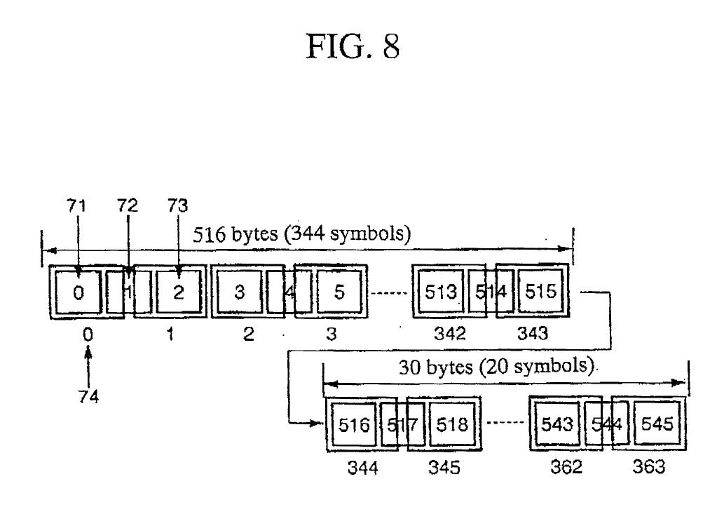

FIG. 8 is a diagram of a symbol structure on a top row of the internal code error correcting code of FIG. 7 in a fourth embodiment in accordance with the present invention. 71 represents a data byte number 0 on a column number “0”. 72 represents a data byte number 1 on a column number “1”, 73 represents a data byte number 2 on a column number “2”. A largest data byte number is 515. The data on the single row comprise 516 bytes. The internal code error correcting code comprises data byte numbers 516 to 545 of 40 bytes or 30 bytes.

74 represents a symbol of the symbol number “0”, wherein this single symbol comprises 12 bits which comprise 8-bits of the data byte number “0” and 4-bits of the data byte number “1”. In case that the single symbol comprises the data byte numbers “0” and “1”, it is general that the production method of the internal code error correcting code is the same as that of the external code error correcting code. It is, however, possible that the production method of the internal code error correcting code is different from that of the external code error correcting code. The data symbol comprises the symbol numbers “0” to “343”, or 344 symbols. The internal code error correcting code comprises 20 symbols, for example, symbol numbers “344” to “363”. The internal code error correcting code is the Reed-Solomon code over GF (2¹²). The Reed-Solomon code of 20 symbols is produced for the data of 344 symbols. This calculation will be repeated for 768 rows of the data table 12 and 64 rows of the external code error correcting code 23, so that the Reed-Solomon codes are produced and set as the internal code error correcting codes 64 for 832 rows in total.

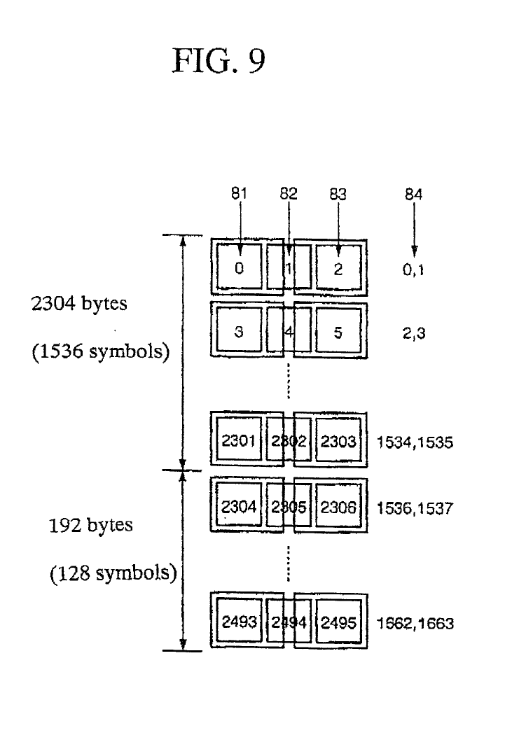

FIG. 9 is a diagram of a symbol structure on columns “0” and “1” of the external code error correcting code of FIG. 7 in a fourth embodiment in accordance with the present invention. 81 represents a data byte number 0 on a row number “0” and a column number “0”. 82 represents a data byte number 1 on a row number “0” and a column number “1”. 83 represents a data byte number 2 on a row number “0” and a column number “2”. A largest data byte number is 2303. The data on the single row comprise 2304 bytes. The external code error correcting code comprises data byte numbers 2304 to 2395 of 192 bytes.

84 represents two symbols of the symbol numbers “0,1”, wherein this two symbols comprise 12 bits which comprise three data bytes of the data byte numbers “0”, “1” and “2”. In case that the single symbol comprises the data byte numbers “0”, “1” and “2”, for the symbol number “0”, the data byte number “0” may bc replaced by MSB 8-bits in the 12-bits of the symbol number “0”, and MSB 4-bits of the data byte number 1 may be replaced by LSB 4-bits of the symbol number “0”. For the symbol number “1”, LSB 4-bits of the data byte number “1” may be replaced by MSB 4-bits of the symbol number “1”, and the data byte number 2 may be replaced by LSB 8-bits of the symbol number “1”. The data symbol comprises the symbol numbers “0” to “1535”, or 1536 symbols.

The external code error correcting code comprises 128 symbols, for example, symbol numbers “1536” to “1663”. The external code error correcting code is the Reed-Solomon code over GF (2¹²). The Reed-Solomon code of 1280 symbols is produced for the data of 1536 symbols. This calculation will be repeated for 516 columns, so that the Reed-Solomon codes are produced and set as the external code error correcting codes 63.

As a modification, it is possible that the additions of the external code error correcting codes of even symbol numbers are independently executed from the additions of the external code error correcting codes of odd symbol numbers. The even symbol numbers are the symbol number “0”, the symbol number “2”, the symbol number “4”, - - - the symbol number “1534”. 768 symbols are of the even symbol numbers. The corresponding external code error correcting codes are the symbol number “1536”, the symbol number “1538”, - - - the symbol number “1562”. 64 symbols are of the corresponding external code error correcting codes. The odd symbol numbers are the symbol number “1”, the symbol number “3”, the symbol number “5”, - - - the symbol number “1535”. 768 symbols are of the odd symbol numbers. The corresponding external code error correcting codes are the symbol number “1537”, the symbol number “1539”, - - - the symbol number “1563”. 64 symbols are of the corresponding external code error correcting codes. This calculation will be repeated for 516 columns, so that the Reed-Solomon codes are produced and set as the external code error correcting codes 64.

Fifth Embodiment:

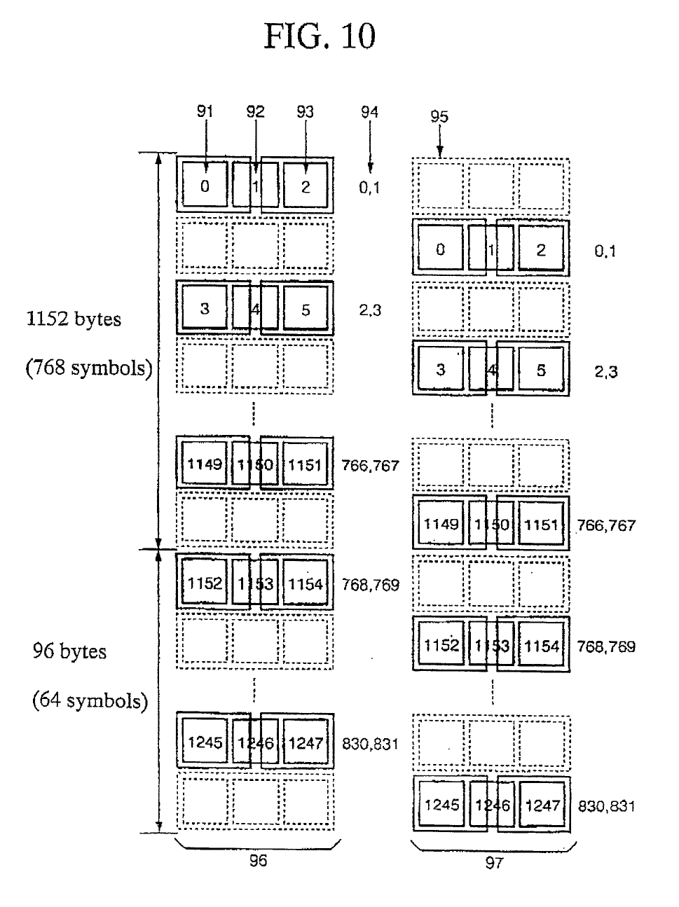

A fifth embodiment according to the present invention will be described in detail with reference to the drawings. The fifth embodiment is different from the fourth embodiment in the method of producing the external code error correcting codes. FIG. 10 is a diagram of a symbol structure on columns “0” and “1” of the external code error correcting code in a fifth embodiment in accordance with the present invention. In a recording side, the external code error correcting code is added before the internal code error correcting code is then added. In a reproducing side, the internal code error correcting code is decoded before the external code error correcting code is then decoded. 96 represents a block of even number rows and column numbers “0”, “1” and “2”. 97 represents an adjacent block of odd number rows and column numbers “0”, “1” and “2”.

In the block 96, 91 represents a data byte number 0 on a row number “0” and a column number “0”. 92 represents a data byte number 1 on a row number “0” and a column number “1”. 93 represents a data byte number 21 on a row number “0” and a column number “2”. A largest data byte number is 1151 on the row number “766” and the column number “2”. The data on the block 96 comprise 1152 bytes. The external code error correcting code comprises a data byte number 1152 on the row number “768” and the column number “0” to a data byte number 1247 on the row number “830” and the column number “2”. The external code error correcting code comprises 96 bytes.

In the block 97, a data byte number 0 is on a row number “1” and a column number “0”. A data byte number 1 on a row number “1” and a column number “1”. A largest data byte number is 1151 on the row number “767” and the column number “2”. The data on the block 97 comprise 1152 bytes. The external code error correcting code comprises a data byte number 1152 on the row number “769” and the column number “0” to a data byte number 1247 on the row number “831” and the column number “2”. The external code error correcting code comprises 96 bytes. 95 with a broken line represents a data belonging to other block.

In the block 96, 94 represents two symbols of the symbol numbers “0,1”, wherein this two symbols comprise 12 bits which comprise three data bytes of the data byte numbers “0”, “1” and “2”. In case that the single symbol comprises the data byte numbers “0”, “1” and “2”, for the symbol number “0”, the data byte number “0” may be replaced by MSB 8-bits in the 12-bits of the symbol number “0”, and MSB 4-bits of the data byte number 1 may be replaced by LSB 4-bits of the symbol number “0”. For the symbol number “1”, LSB 4-bits of the data byte number “1” may be replaced by MSE 4-bits of the symbol number “1”, and the data byte number 2 may be replaced by LSB 8-bits of the symbol number “1”. The data symbol comprises the symbol numbers “0” to “767”, or 768 symbols. The external code error correcting code comprises the symbol numbers “768” to “831”, or 64 symbols.

In the block 97, 94 two symbols of the symbol numbers “0,1”, comprise 12 bits which comprise three data bytes of the data byte numbers “0”, “1” and “2”. In case that the single symbol comprises the data byte numbers “0”, “1” and “2”, for the symbol number “407” the data byte number “0” may be replaced by MSB 8-bits in the 12-bits of the symbol number “0”, and MSB 4-bits of the data byte number 1 may be replaced by LSB 4-bits of the symbol number “1”. For the symbol number “1”, LSB 4-bits of the data byte number “1” may be replaced by MSB 4-bits of the symbol number “1”, and the data byte number 2 may be replaced by LSB 8-bits of the symbol number “1”. The data symbol comprises the symbol numbers “0” to “767”, or 768 symbols. The external code error correcting code comprises the symbol numbers “768” to “831”, or 64 symbols.

In each of the blocks 96 and 97, the external code error correcting code is the Reed-Solomon code over GF (2¹²). The Reed-Solomon code of 64 symbols is produced for the data of 768 symbols. In each of the blocks 96 and 97, this calculation will be repeated for 516 columns including the data table 62 and the external code error correcting code 63, so that the Reed-Solomon codes are produced and set as the external code error correcting codes 63.

As a modification, it is possible that the additions of the external code error correcting codes of even symbol numbers are independently executed from the additions of the external code error correcting codes of odd symbol numbers. In the block 96, the even symbol numbers are the symbol number “0”, the symbol number “2”, the symbol n umber “4”, - - - the symbol number “766”. 384 symbols are of the even symbol numbers. The corresponding external code error correcting codes are the symbol number “768”, the symbol number “770”, - - - the symbol number “830”. 32 symbols are of the corresponding external code error correcting codes. The odd symbol numbers are the symbol number “1”, the symbol number “3”, the symbol number “5”, - - - the symbol number “767”. 384 symbols are of the odd symbol numbers. The corresponding external code error correcting codes are the symbol number “769”, the symbol number “771”, - - - the symbol number “831”. 32 symbols are of the corresponding external code error correcting codes. For the block 97, the same calculation will be made. This calculation will be repeated for 516 columns, so that the Reed-Solomon codes are produced and set as the external code error correcting codes 63.

In FIGS. 6 and 10, for adding the external code error correcting codes, data detentions are made for the rows alternatively for adding the external code error correcting codes to the rows alternatively, so that the calculation is made for two blocks on each column. It is also possible that for adding the external code error correcting codes, data detentions are made for every three rows with leaving out two rows in the every three rows. It is further possible to execute the data detentions for every plural rows. For adding the internal code error correcting codes, data detentions are made for the rows alternatively for adding the internal code error correcting codes to the rows alternatively, so that the calculation is made for two blocks on each column. It is also possible that for adding the internal code error correcting codes, data detentions are made for every three rows with leaving out two rows in the every three rows. It is further possible to execute the data detentions for every plural rows.

A size of the logic segment is generally 2 k-bytes. This 2 k-bytes logic segment may, in case, comprise 2048 bytes of data only, or in case comprise 2064 bytes which includes the 2048 bytes of data and 16 bytes of informations such as the error correcting codes.

In the foregoing embodiments, the calculations of the external code error correcting codes are made in the column direction, and the calculations of the internal code error correcting codes are made in the row direction. The sectors and the logic segments are isolated by lines of the row directions. It is also possible that the calculations of the external code error correcting codes are made in the row direction, and the calculations of the internal code error correcting codes are made in the column direction, The sectors and the logic segments are isolated by lines of the column directions.

Sixth Embodiment:

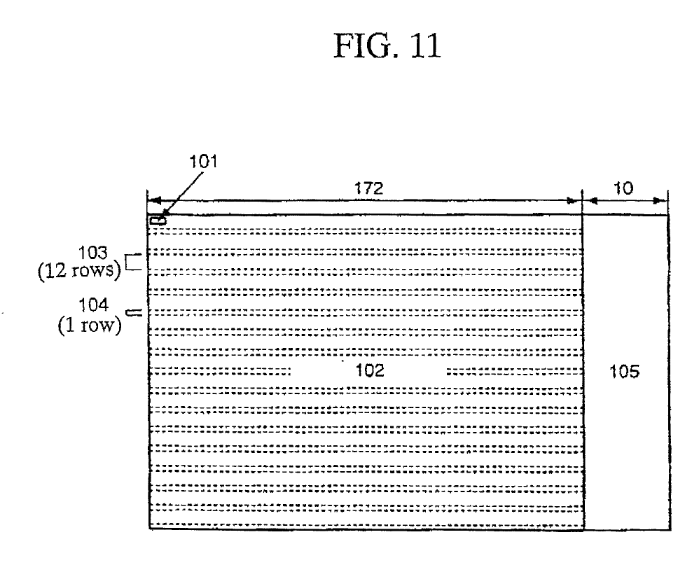

A sixth embodiment according to the present invention will be described in detail with reference to the drawings. FIG. 11 is a diagram illustrative of a novel structure of a block table of ECC for DVD in a sixth embodiment in accordance with the present invention.

One symbol comprises 8 bits. 102 represents a data table. 103 represents each sector which comprises twelve rows. 104 represents each external code error correcting code which comprises a single row. The each external code error correcting code 104 follows to the end of the each sector 103. The data table includes a plurality of spaces of a single row, each of which follows to every twelve rows of data, so that the each external code error correcting code 104 is placed on the each space, whereby the external code correcting codes are distributed in the data table, so as to approximately averaging the undecodable data byte numbers in the error correcting operations. Further, the external code correcting codes are placed in the sequences of recording operations, for which reason it is unnecessary to re-sequence the external code correcting codes for shortening the necessary process time and allowing a circuit scale down.

Seventh Embodiment:

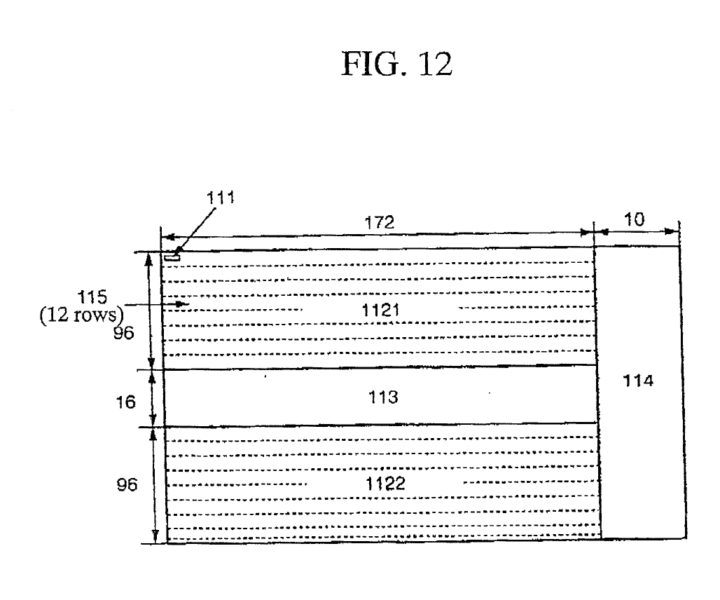

A seventh embodiment according to the present invention will be described in detail with reference to the drawings. FIG. 12 is a diagram illustrative of a novel structure of a block table of ECC for DVD in a seventh embodiment in accordance with the present invention.

One symbol comprises 8 bits. 111 represents each symbol. 1121 and 1122 represent first and second data tables, respectively. 113 represents each external code error correcting code. 114 represents each internal code error correcting code. 115 represents each sector which comprises twelve rows. The each external code error correcting codes 113 are placed on a center region between the first and second data tables 1121 and 1122, so that a burst error having appeared in the center region can be decoded. Namely, the external code correcting codes are concentrated in the center region for reducing the byte number of the undecodable data if the burst error has appeared in the center region of the block table. It is tended that a probability in appearance of the burst errors, which is not correctable, on the center region is higher than that on the end region. Further, the external code correcting codes are placed in the sequences of recording operations, for which reason it is unnecessary to re-sequence the external code correcting codes for shortening the necessary process time and allowing a circuit scale down.

The data and the external and internal code error correcting codes, which are placed on the error correcting code block table, are coded and then recorded onto the disk. If the symbol length of the data table is equal to the data bit length of the recording code table, the error on the disk in the reproduction provides the data bit unit on the recording code table and the symbol unit on the error correcting code block table, thereby allowing the error correction in the unit of the single symbol. This allows a desirable efficient error correction. It is possible that the single symbol of 16-bits is converted to a 24-bits recording code. This technique can be realized by using the conventional conversion technique disclosed in Japanese laid-open patent publication No. 11-062486.

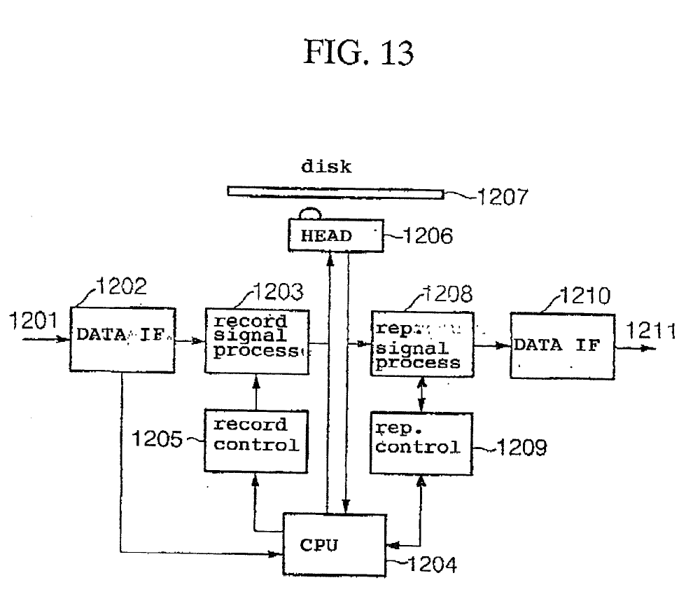

The above described present inventions in the foregoing first to seventh embodiments can be realized by using any available digital data recording and transmitting systems, typical one of which will be described hereinafter with reference to the drawing. FIG. 13 is a block diagram illustrative of a digital data recording and transmitting system to be used for realizing the present invention.

The system includes a first data interface 1202, a recording signal processor 1203, a CPU controller 1204, a recording controller 1205, an optical head 1206, a disk 1207, a reproducing signal processor 1208, a reproducing controller 1209, and a second data interface 1210. The first data interface 1202 receives inputs of digital data and isolate the same into image and voice data and control data. The recording signal processor 1203 is electrically coupled to the first data interface 1202 for receiving the image and voice data and control data, so that the recording signal processor 1203 adds the external and internal code error correcting codes and codes for recording. The recording controller 1205 is electrically coupled to the CPU controller 1204 and the recording signal processor 1203 for controlling the recording signal processor 1203 under the control by the CPU controller 1204. The reproducing signal processor 1208 is electrically coupled to the optical head 1206 for decoding the recorded codes and performing the error corrections by the external and internal code error correcting codes for separating the decoded data into the image and voice data and control data. The image and voice data are supplied to the second data interface 1210, so that the second data interface 1210 output digital data. The control data are supplied through the reproducing controller 1209 to the CPU controller 1204 The reproducing controller 1209 controls the reproducing process of the reproducing signal processor 1208 under the control by the CPU controller 1204.

For recording the data into the disk 1207, digital data 1201 are entered into the first data interface 1202 for separating the digital data 1201 into the image and voice data and control data. The control data are supplied to the CPU controller 1204. The image and voice data are supplied to the recording signal processor 1203.

The CPU controller 1204 analyzes the control data to decide the sequences in recording to the disk 1207. The recording signal processor 1203 adds the external and internal code error correcting codes and codes to the image and voice data and control data, and coding the image and voice data for recording. The CPU controller 1204 controls the optical head 1206 and a spindle motor as well as controls the recording controller 1205 to render the recording signal processor 1203 supply the recording data to the optical head 1206, whereby the recording data are stored to the disk 1207.

For reproducing the data stored in the disk 1207, the optical head 1206 reads the data out of the disk 1207 and then supplies the data to the CPU controller 1204 and the reproducing signal processor 1208. The reproducing signal processor 1208 decodes the recorded code data and performs the error corrections based on the external and internal code error correcting codes for separating the decoded data into the image and voice data and control data. The control data are supplied through the reproducing controller 1209 to the CPU controller 1204. The reproducing controller 1209 controls the reproducing process of the reproducing signal processor 1208 under the control by the CPU controller 1204. The image and voice data are supplied to the second data interface 1210, so that the second data interface 1210 output digital data.

The storage medium usable in the present application may include any mediums capable of storing any data including digital data, image data, voice data and system data, and the storage medium, for example, includes optical disks such as optical magnetic disks and phase change disks, magnetic disks, and magnetic tapes.

As described above, in accordance with the present invention, one symbol comprises n-bits (n is an integer more than 8), and error correcting codes comprise Reed-Solomon codes over GF (2ⁿ), so that a total code length including data and error correcting codes corresponds to 256 symbols or more. A data array is formed over plural rows and plural columns, wherein data corresponds to 256 symbols or more are arrayed for every rows and/or columns. External code error correcting codes are calculated for all column-directional alignments of data in a column direction. Internal code error correcting codes are calculated for all row-directional alignments of data in a column direction or the external code error correcting codes. The data and the calculated external and internal code error correcting codes are recorded and transferred. As a result, a table larger than 256×256 arrays of symbols can be prepared, whereby the number of error-correctable symbols is increased and also the error-correction capability to the random errors in symbol unit is also improved.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A method of implementing at least one of recording and transmitting digital data, under conditions that a total code length including data and error correcting codes corresponds to not less than 256 symbols, and each of said symbols comprises n-bits, where n is larger than 8.

2. The method as claimed in claim 1, further comprising the steps of:
arraying said data and said error correcting codes in a matrix of plural rows and plural columns;
calculating external code error correcting codes for all column-directional alignments of data in a column direction, and further internal code error correcting codes for all row-directional alignments of data in a column direction or the external code error correcting codes; and
recording the data and the calculated external and internal code error correcting codes.

3. The method as claimed in claim 1, wherein said error correcting codes are Reed-Solomon codes over GF (2ⁿ).

4. The method as claimed in claim 1, wherein said data are arrayed in a matrix of plural rows and plural columns, and a total data length corresponds to a number of symbols, which is equal to or multiply of 2064.

5. The method as claimed in claim 1, wherein said data are arrayed in a matrix of plural rows and plural columns, and a total data length corresponds to a number of symbols which is equal to or multiply of 33024.

6. The method as claimed in claim 1, wherein said data are arrayed in a matrix of plural rows and plural columns, and a total data length of the rows corresponds to a number of symbols which is equal to or multiply of 192.

7. The method as claimed in claim 1, wherein said data are arrayed in a matrix of plural rows and plural columns, and a total data length of the columns corresponds to a number of symbols which is equal to or multiply of 172.

8. The method as claimed in claim 2, wherein external code error correcting codes are isolated into a first block comprising even number rows and a second block comprising odd number rows.

9. The method as claimed in claim 8, wherein calculations of said external code error correcting codes are made with a row-directional increment of 2 or more integer.

10. The method as claimed in claim 1, wherein calculations of said error correcting codes are made with a second column-directional increment of 2 or more integer.

11. The method as claimed in claim 1, further comprising the steps of:
arraying said data and said error correcting codes in a matrix array of plural rows and plural columns;
dividing said data and said error correcting codes into a plurality of sectors; and
adding at least an additional information to each of said sectors to form each logic segment.

12. The method as claimed in claim 11, wherein said each segment has a segment size of 2048 bytes.

13. The method as claimed in claim 11, wherein said each segment has a segment size of 2064 bytes, which comprises 2048 bytes for data and 16 bytes for segment header.

14. The method as claimed in claim 11, wherein each external code error correcting code is placed following to an end of said each sector.

15. The method as claimed in claim 11, wherein each external code error correcting code is placed on a center region of said matrix array.

16. The method as claimed in claim 15, wherein a length of said each symbol is equal to a bit length of coded data.

17. A method of preparing a table including at least data and error correcting codes, wherein a total code length including said data and said error correcting codes corresponds to not less than 256 symbols, and each of said symbols comprises n-bits, where n is larger than 8.

18. The method as claimed in claim 17, further comprising the steps of:
arraying said data and said error correcting codes in a matrix of plural rows and plural columns; and
calculating external code error correcting codes for all column-directional alignments of data in a column direction, and further internal code error correcting codes for all row-directional alignments of data in a column direction or the external code error correcting codes.

19. The method as claimed in claim 17, wherein said error correcting codes are Reed-Solomon codes over GF (2ⁿ).

20. The method as claimed in claim 17, wherein said data are arrayed in a matrix of plural rows and plural columns, and a total data length corresponds to a number of symbols, which is equal to or multiply of 2064.

21. The method as claimed in claim 17, wherein said data are arrayed in a matrix of plural rows and plural columns, and a total data length corresponds to a number of symbols which is equal to or multiply of 33024.

22. The method as claimed in claim 17, wherein said data are arrayed in a matrix of plural rows and plural columns, and a total data length of the rows corresponds to a number of symbols which is equal to or multiply of 192.

23. The method as claimed in claim 17, wherein said data are arrayed in a matrix of plural rows and plural columns, and a total data length of the columns corresponds to a number of symbols which is equal to or multiply of 172.

24. The method as claimed in claim 18, wherein external code error correcting codes are isolated into a first block comprising even number rows and a second block comprising odd number rows.

25. The method as claimed in claim 24, wherein calculations of said external code error correcting codes are made with a row-directional increment of 2 or more integer.

26. The method as claimed in claim 17, wherein calculations of said error correcting codes are made with a second column-directional increment of 2 or more integer.

27. The method as claimed in claim 17, further comprising the steps of:
arraying said data and said error correcting codes in a matrix array of plural rows and plural columns;
dividing said data and said error correcting codes into a plurality of sectors; and
adding at least an additional information to each of said sectors to form each logic segment.

28. The method as claimed in claim 27, wherein said each segment has a segment size of 2048 bytes.

29. The method as claimed in claim 27, wherein said each segment has a segment size of 2064 bytes, which comprises 2048 bytes for data and 16 bytes for segment header.

30. The method as claimed in claim 27, wherein each external code error correcting code is placed following to an end of said each sector.

31. The method as claimed in claim 27, wherein each external code error correcting code is placed on a center region of said matrix array.

32. The method as claimed in claim 15, wherein a length of said each symbol is equal to a bit length of coded data.

33. A table including at least data and error correcting codes, wherein a total code length including said data and said error correcting codes corresponds to not less than 256 symbols, and each of said symbols comprises n-bits, where n is larger than 8.

34. The table as claimed in claim 33, wherein said table comprises a matrix array of said data and said error correcting codes over plural rows and plural columns; and said error correcting codes includes external code error correcting codes for all column-directional alignments of data in a column direction, and internal code error correcting codes for either one of all row-directional alignments of data in a column direction or the external code error correcting codes.

35. The table as claimed in claim 33, wherein said error correcting codes are Reed-Solomon codes over GF (2ⁿ).

36. The table as claimed in claim 33, wherein said table has a data array of plural rows and plural columns, and a total data length corresponds to a number of symbols, which is equal to or multiply of 2064.

37. The table as claimed in claim 33, wherein said table has a data array of plural rows and plural columns, and a total data length corresponds to a number of symbols which is equal to or multiply of 33024.

38. The table as claimed in claim 33, wherein said table has a data array of plural rows and plural columns, and a total data length of the rows corresponds to a number of symbols which is equal to or multiply of 192.

39. The table as claimed in claim 33, wherein said table has a data array of plural rows and plural columns, and a total data length of the columns corresponds to a number of symbols which is equal to or multiply of 172.

40. The table as claimed in claim 34, wherein external code error correcting codes are isolated into a first block comprising even number rows and a second block comprising odd number rows.

41. The table as claimed in claim 33, wherein said table has a matrix array comprising said data and said error correcting codes over plural rows and plural columns, and said matrix array has a plurality of logic segments, and each of said logic segments includes each sector and an additional information, and said each sector including at least one of said data and said error correcting codes.

42. The table as claimed in claim 41, wherein said each segment has a segment size of 2048 bytes.

43. The table as claimed in claim 41, wherein said each segment has a segment size of 2064 bytes, which comprises 2048 bytes for data and 16 bytes for segment header.

44. The table as claimed in claim 41, wherein each external code error correcting code is positioned following to an end of said each sector.

45. The table as claimed in claim 41, wherein each external code error correcting code is positioned on a center region of said matrix array.

46. The table as claimed in claim 45, wherein a length of said each symbol is equal to a bit length of coded data.

47. The table as claimed in claim 33, wherein said table comprises an error correcting code block table.

48. The table as claimed in claim 33, wherein said table has a size larger than 256×256 arrays of symbols.

49. A system for recording and transmitting digital data, wherein said system includes a table as claimed in claim 33.

50. A method of using a table as claimed in claim 33.
